(19) United States
(12) Patent Application Publication
(10) Pub. No.: US 2025/0391782 A1
(43) Pub. Date: Dec. 25, 2025

(54) SEMICONDUCTOR WAFER

(71) Applicant: Novatek Microelectronics Corp., Hsinchu (TW)

(72) Inventors: Ting-Yu Hu, Hsinchu County (TW); Chi Shih Yu, Hsinchu County (TW); Chia-Hong Gao, Chiayi County (TW); Ying-Cheng Liu, Tainan City (TW)

(73) Assignee: Novatek Microelectronics Corp., Hsinchu (TW)

(21) Appl. No.: 18/792,578

(22) Filed: Aug. 2, 2024

(30) Foreign Application Priority Data
Jun. 24, 2024 (TW) 113123371

(51) Int. Cl. H01L 23/544; H01L 21/78; H01L 23/58

(52) U.S. Cl. CPC H01L 23/544; H01L 21/78; H01L 23/585; H01L 2223/54426

(57) ABSTRACT

A wafer structure includes a substrate, a scribe line, a chip circuit pattern, and a peripheral metal pattern. The scribe line defines a chip unit on the substrate. The chip circuit pattern is disposed in a central region of the chip unit. The peripheral metal pattern is disposed in a peripheral region of the chip unit surrounding the central region. The peripheral metal pattern includes a seal ring pattern surrounding the central region and an alignment pattern disposed between the scribe line and the seal ring pattern.

### CROSS-REFERENCE TO RELATED APPLICATION

This application claims the priority benefit of Taiwan application serial no. 113123371, filed on Jun. 24, 2024. The entirety of the above-mentioned patent application is hereby incorporated by reference herein and made a part of this specification.

### BACKGROUND OF THE INVENTION

### Field of the Invention

The disclosure relates to a wafer structure.

### Description of Related Art

Generally, an integrated circuit includes a plurality of layers having different patterns, and each of the layers is formed by a photolithography process. Also, features on successively patterned layers are spatially related to other features. Therefore, during the fabrication process, each of the patterned layers needs to be aligned with the previous patterned layer. To achieve this, the substrate or a dielectric layer formed thereon is typically provided with a plurality of alignment marks (also called alignment targets), so that the positions of the alignment marks are used to determine the positions of previously exposed patterns.

Traditional pattern alignment techniques generally form alignment (or identification) marks on the scribe lines of each die. However, in order to improve productivity, the scribe lines on the wafer are gradually reduced to increase the number of dies per wafer. However, this approach may readily cause the alignment mark located on the scribe line to be cut when the wafer is cut, thus causing the metal layer of the alignment mark to be exposed and affecting the appearance.

### SUMMARY OF THE INVENTION

The disclosure provides a wafer structure in which the position of the alignment pattern thereof does not affect the appearance of the product after a cutting process, and the width of a scribe line of the wafer may be effectively reduced, thereby increasing the chip throughput of each wafer.

A semiconductor wafer of the disclosure includes a substrate, a scribe line, a chip circuit pattern, and a peripheral metal pattern. The scribe line defines a chip unit on the substrate. The chip circuit pattern is disposed in a central region of the chip unit. The peripheral metal pattern is disposed in a peripheral region of the chip unit surrounding the central region. The peripheral metal pattern includes a seal ring pattern surrounding the central region and an alignment pattern disposed between the scribe line and the seal ring pattern.

In an embodiment of the disclosure, the seal ring pattern includes a chamfer to vacate a corner region in the chip unit, and the alignment pattern is disposed in a corner region vacated by the chamfer.

In an embodiment of the disclosure, the alignment pattern is spaced apart from the seal ring pattern by a first distance.

In an embodiment of the disclosure, an outer edge of the alignment pattern is spaced apart from an inner edge of the scribe line by a second distance.

In an embodiment of the disclosure, the peripheral metal pattern further includes a plurality of dummy metal pads evenly distributed between the seal ring pattern and the alignment pattern.

In an embodiment of the disclosure, an outer edge of the alignment pattern is substantially collinear with an outer edge of the corresponding seal ring pattern.

In an embodiment of the disclosure, the alignment pattern is not overlapped with the scribe line when viewed from a top view direction.

In an embodiment of the disclosure, the alignment pattern and the seal ring pattern are disposed on a same plane.

In an embodiment of the disclosure, the chip circuit pattern is electrically insulated from the peripheral metal pattern.

In an embodiment of the disclosure, the alignment pattern is L-shaped, square-shaped, cross-shaped, Z-shaped, or hourglass-shaped.

In an embodiment of the disclosure, the seal ring pattern includes a plurality of seal ring pattern layers disposed on the substrate in an overlapping manner.

In an embodiment of the disclosure, the alignment pattern includes a plurality of alignment pattern layers disposed on the substrate in an overlapping manner and respectively disposed on a same layer as the corresponding plurality of seal ring pattern layers.

In an embodiment of the disclosure, the seal ring pattern includes an inner seal ring pattern surrounding the central region and an outer seal ring pattern surrounding the inner seal ring pattern.

In an embodiment of the disclosure, the alignment pattern is disposed between the scribe line and the outer seal ring pattern.

A chip structure of the disclosure includes a substrate, a chip circuit pattern, and a peripheral metal pattern. The substrate includes a central region and a peripheral region surrounding the central region. The chip circuit pattern is disposed at the central region. The peripheral metal pattern is disposed at the peripheral region and includes a seal ring pattern surrounding the chip circuit pattern and an alignment pattern disposed outside a closed region defined by the seal ring pattern.

In an embodiment of the disclosure, the alignment pattern is disposed between an outer edge of the chip structure and the seal ring pattern.

In an embodiment of the disclosure, the seal ring pattern has a chamfer corresponding to a corner of the substrate, and the alignment pattern is disposed at the corner vacated by the chamfer.

A wafer structure of disclosure includes a substrate, a scribe line, a chip, a seal ring, and an alignment mark. The scribe line defines a chip unit on the substrate. The chip is disposed in the chip unit. The seal ring surrounds the chip and is located between the scribe line and the chip. The alignment mark is disposed between the scribe line and the seal ring.

Based on the above, in the wafer structure of the disclosure, the alignment pattern is disposed within the range defined by the scribe line and located at the region located outside the closed region defined by the seal ring pattern. Therefore, it is possible to avoid the issue that the alignment pattern on the scribe line is cut during the chip cutting process, causing the metal layer to be exposed and affecting the appearance of the chip. Moreover, since there is no need to worry about cutting the alignment pattern during the chip cutting process, the width of the scribe line may be further reduced, so that the chip units on the wafer are arranged more densely, thereby increasing the number of dies per wafer and increasing the chip throughput of each wafer.

### BRIEF DESCRIPTION OF THE DRAWINGS

FIG. 1 is a schematic top view of a wafer structure according to an embodiment of the disclosure.

FIG. 2 is a partially enlarged schematic diagram of a wafer structure according to an embodiment of the disclosure.

FIG. 3A is a schematic top view of a chip structure according to an embodiment of the disclosure.

FIG. 3B is a schematic top view of a chip structure according to an embodiment of the disclosure.

FIG. 4 is a partially enlarged schematic diagram of a chip unit of a wafer structure according to an embodiment of the disclosure.

FIG. 5 is a schematic top view of an alignment pattern of a wafer structure according to an embodiment of the disclosure.

FIG. 6 is a schematic top view of an alignment pattern of a wafer structure according to a different embodiment of the disclosure.

FIG. 7A is a partial cross-sectional view of a wafer structure according to an embodiment of the disclosure.

FIG. 7B is a partial cross-sectional view of a wafer structure according to an embodiment of the disclosure.

### DESCRIPTION OF THE EMBODIMENTS

The aforementioned and other technical contents, features, and effects of the invention will be clearly presented in the following detailed description of each embodiment with reference to the drawings. The directional terms mentioned in the following embodiments, such as: “up”, “down”, “front”, “back”, “left”, “right”, etc., are only reference directions of the figures. Accordingly, the directional terms used are illustrative, not limiting, of the invention. Moreover, in the following embodiments, the same or similar elements are given the same or similar reference numerals.

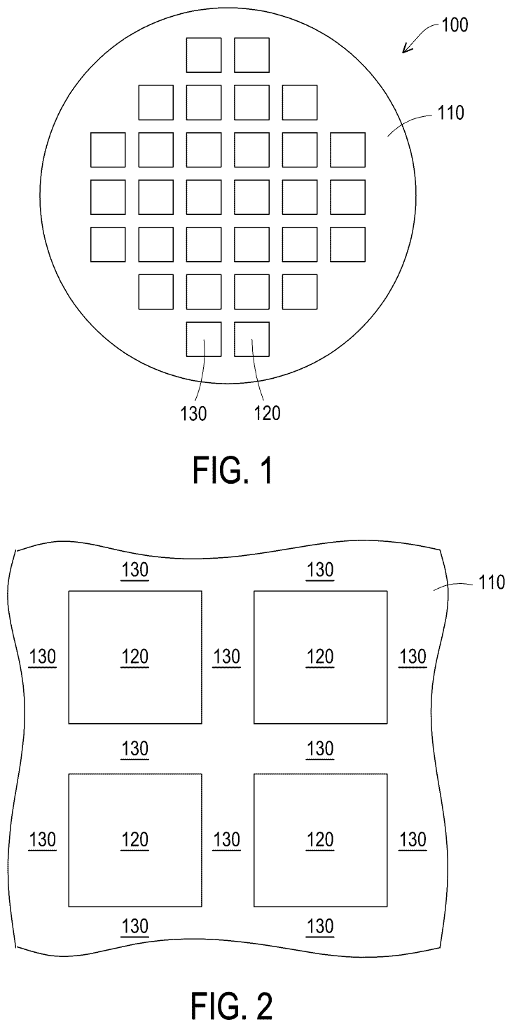

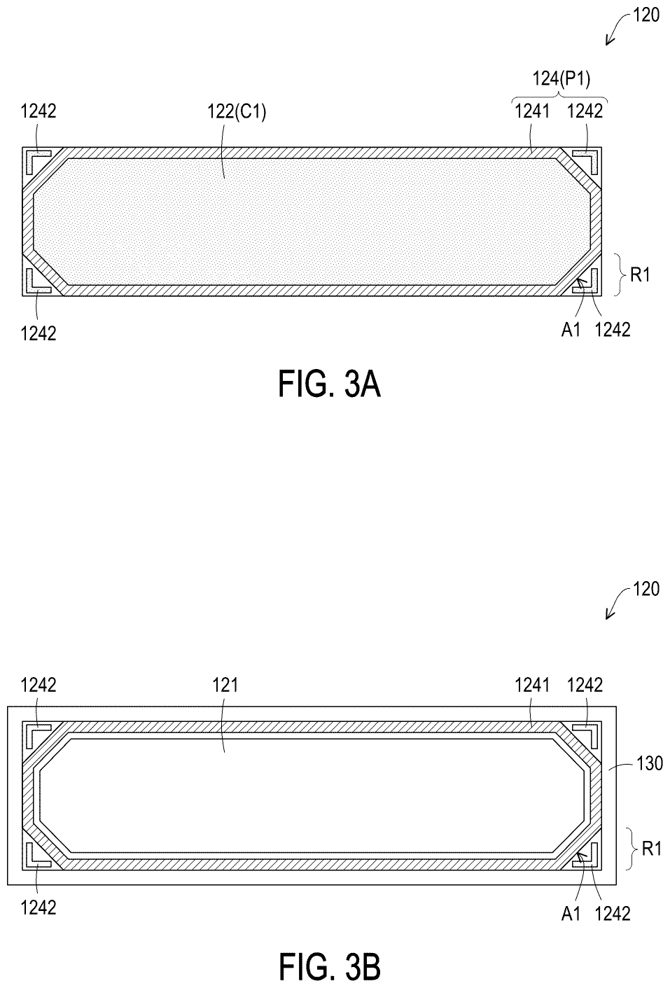

FIG. 1 is a schematic top view of a wafer structure according to an embodiment of the disclosure. FIG. 2 is a partially enlarged schematic diagram of a wafer structure according to an embodiment of the disclosure. FIG. 3A is a schematic top view of a chip structure according to an embodiment of the disclosure. Referring to FIG. 1 to FIG. 3A, in some embodiments, a wafer structure 100 includes a substrate 110. The substrate 110 may be formed by silicon, germanium (Ge), or other suitable semiconductor materials. In some embodiments, the substrate 110 may be formed by a compound semiconductor such as silicon carbide (SiC), gallium arsenide (GaAs), indium arsenide (InAs), or indium phosphide (InP). In some embodiments, the substrate 110 is formed by a compound semiconductor such as silicon germanium (SiGe), silicon germanium carbide (SiGeC), gallium arsenic phosphide (GaAsP), or gallium indium phosphide. In some other embodiments, the substrate 110 may include a silicon-on-insulator (SOI) substrate or a germanium-on-insulator (GOI) substrate. In some examples, the substrate 110 may include a doped epitaxial layer. In some examples, the silicon substrate may include a multilayer composite semiconductor structure. Alternatively, the wafer structure 100 may include a non-semiconductor material, such as a suitable material such as a glass substrate, quartz, or calcium fluoride. In some embodiments, the thickness of the substrate 110 may be approximately greater than 500 microns (μm).

In some embodiments, the wafer structure 100 may include the substrate 110, a scribe line 130, a chip circuit pattern 122, and a peripheral metal pattern 124. The substrate 110 has a front surface and a back surface opposite to the front surface, and the scribe line 130 defines a plurality of chip units 120 on the substrate 110. Specifically, the plurality of chip units 120 shown in FIG. 1 and FIG. 2 are defined on the front side surface of the substrate 110 by the scribe line 130. Generally, the wafer structure 100 is used as a manufacturing carrier during the production of chips. After the semiconductor process is completed, the plurality of chip units 120 are formed on the wafer structure 100. Next, these chip units 120 are separated by a chip cutting or singulation process to form a plurality of mutually separated chip structures 120 (the cut chip structures 120 may be as shown in FIG. 3A). The singulation process may include mechanical cutting or laser cutting to cut off the regions between the respective chip units 120 along the scribe line 130. That is, the scribe line 130 is the region between adjacent chip units 120. In some embodiments, there are no functional devices in the scribe line 130. In some embodiments, the scribe line 130 does not include metal, for example, the scribe line 130 does not include any metal layer or metal structure. In some embodiments, the scribe line 130 may include a plurality of test pads (not shown) for testing purposes.

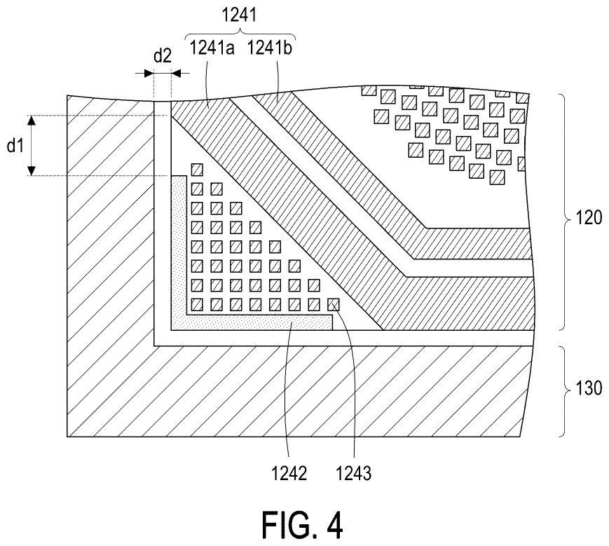

FIG. 3A is a schematic top view of a chip unit of a wafer structure according to an embodiment of the disclosure. FIG. 4 is a partially enlarged schematic diagram of a chip unit of a wafer structure according to an embodiment of the disclosure. Please refer to FIG. 3A and FIG. 4 simultaneously. In some embodiments, the chip units 120 may include a central region C1 and a peripheral region P1 surrounding the central region C1. The chip circuit pattern 122 is disposed at the central region C1, the peripheral metal pattern 124 is disposed at the peripheral region P1 to surround the chip circuit pattern 122, and the chip circuit pattern 122 is electrically insulated from the peripheral metal pattern 124. It should be noted that the above orientation terms such as the central region C1 and the peripheral region P1 are relative terms, and the central region C1 is not necessarily located at the center of the chip units 120. The elements of the disclosure may be positioned in many different orientations. Thus, the directional terminology is used for illustrative purposes and is not limiting in any way.

In some embodiments, the central region C1 may also be called the active region of the chip, and may be formed by a plurality of elements, such as an active element and a passive element located on the substrate 110. The central region C1 includes most of the high-density active circuits of the chip units 120, that is, the chip circuit pattern 122. Specifically, the chip circuit pattern 122 may include a plurality of layers, such as an active layer used to define an active region of an integrated circuit, a polysilicon layer used to define a gate region of an integrated circuit, a contact layer used to define the contact between the active region and the polycrystalline region, an implant layer, a metal layer, and/or other suitable layers. The multi-layer chip circuit pattern 122 may form various elements, and includes, for example, a passive element such as a resistor, a capacitor, an inductor, such as an active element such as a metal oxide semiconductor field-effect transistor (MOSFET), a complementary metal oxide semiconductor transistor (CMOS), a high-voltage transistor, and/or a high-frequency transistor, other suitable elements, and/or a combination of the above elements. The elements formed on the substrate 110 may be initially isolated from each other, and then the elements are interconnected together by a multi-layer metal interconnect structure to form a functional circuit. Typical interconnect structures include lateral interconnects (such as metal lines or conductive lines) and vertical interconnects (such as vias and contacts).

FIG. 3B is a schematic top view of a chip structure according to an embodiment of the disclosure. Please refer to FIG. 2 and FIG. 3B. In the present embodiment, from a structural perspective, the scribe line 130 defines the plurality of chip units 120 on the wafer structure, wherein each of the chip units 120 includes a chip 121, a seal ring (i.e., a seal ring pattern) 1241, and an alignment mark (i.e., an alignment pattern) 1242. Specifically, the plurality of chip units 120 are defined on the front side surface of the substrate 110 by the scribe line 130. Generally, the wafer structure 100 is used as a manufacturing carrier during the production of chips. After the semiconductor process is completed, the plurality of chip units 120 are formed on the wafer structure 100. That is, the scribe line 130 is the region between adjacent chip units 120. The chips 121 are respectively formed in the chip units 120 defined by the scribe line 130, and each of the chips 121 includes the chip circuit pattern 122. In some embodiments, the chips 121 may be formed by a plurality of elements, such as an active element and a passive element located on the substrate 110. Specifically, the chips 121 may include the multi-layer chip circuit pattern 122, such as an active layer used to define an active region of an integrated circuit, a polysilicon layer used to define a gate region of an integrated circuit, a contact layer used to define the contact between the active region and the polycrystalline region, an implant layer, a metal layer, and/or other suitable layers. The multi-layer chip circuit pattern 122 may form various elements, and includes, for example, a passive element such as a resistor, a capacitor, an inductor, such as an active element such as a metal oxide semiconductor field-effect transistor (MOSFET), a complementary metal oxide semiconductor transistor (CMOS), a high-voltage transistor, and/or a high-frequency transistor, other suitable elements, and/or a combination of the above elements. The elements formed on the substrate 110 may be initially isolated from each other, and then the elements are interconnected together by a multi-layer metal interconnect structure to form a functional circuit. Typical interconnect structures include lateral interconnects (such as metal lines or conductive lines) and vertical interconnects (such as vias and contacts). The seal ring 1241 surrounds the chips 121 and is located between the scribe line 130 and the chips 121, and the alignment pattern 1242 is disposed between the scribe line 130 and the seal ring 1241.

In some embodiments, as shown in FIG. 4, the peripheral metal pattern 124 of the chip units 120 includes the seal ring pattern 1241 surrounding the central region C1 and the alignment pattern 1242 disposed between the scribe line 130 and the seal ring pattern 1241. Specifically, the alignment pattern 1242 is disposed in the range defined by the scribe line 130 and located outside the closed region defined by the seal ring pattern 1241. Therefore, when viewed from the top view direction as shown in FIG. 4, the alignment pattern 1242 is not overlapped with the scribe line 130. It should be noted here that since the scribe line 130 is cut off during the chip cutting process, taking the cut chip structures 120 (as shown in FIG. 3A) as an example, the alignment pattern 1242 is disposed at a region outside the closed region defined by the seal ring pattern 1241. In other words, the alignment pattern 1242 is disposed between the outer edge of the chip structure 120 and the seal ring pattern 1241.

In the present embodiment, the uppermost layer of the chip circuit pattern 122 may include a plurality of pads that may include a plurality of active metal pads and a plurality of dummy metal pads. The dummy metal pads have no electrical function. The active metal pads may be electrically connected to the active element on the substrate by, for example, a pad via and an interconnect structure. The dummy metal pads are electrically insulated from the elements in the chip structure 120. That is, the dummy metal pads may be electrically floating. In some embodiments, the active metal pads and the dummy metal pads have the same top view shape, size, and/or contain the same material. In addition, the active metal pads and the virtual metal pads are formed simultaneously. In alternative embodiments, the active metal pads and the dummy metal pads have different top view shapes and/or different top view dimensions.

As shown in FIG. 3A, the seal ring pattern 1241 surrounds the edge of the chip circuit pattern 122. The seal ring pattern 1241 may form a barrier against moisture, corrosive gases, and chemicals entering the interior of the chip circuit pattern 122, and protect the chip circuit pattern 122 from damages such as cracks and stress caused by the cutting tool. The seal ring pattern 1241 may generally be formed by a conductive material (such as aluminum (Al), aluminum-copper (Al—Cu) alloy, or aluminum-copper-silicon (Al—Cu—Si) alloy) similar to pads (active metal pads and dummy metal pads). In some embodiments, the width of the top view of the seal ring pattern 1241 is about 10 μm, but the disclosure is not limited thereto.

In some embodiments, the seal ring pattern 1241 includes a chamfer A1 to vacate a corner region R1 in the chip units 120, and the alignment pattern 1242 is disposed in the corner region R1 vacated by the chamfer A1. For example, when viewed from a top view direction, the chip units 120 may be rectangles having four corners, and the seal ring pattern 1241 may be provided with chamfers A1 corresponding to the four corners to present an octagonal shape as shown in FIG. 3A to vacate the four corners of the chip units 120, and the alignment pattern 1242 may be correspondingly disposed at the four corners vacated by the chamfers A1. Of course, the disclosure does not limit the shape of the chip units and the seal ring pattern, as long as the number and the position of the chamfers of the seal ring pattern correspond to the number and the position of the corners of the chip units.

Under such a structural configuration, in the present embodiment, the alignment pattern 1242 is disposed in the range defined by the scribe line 130 and located at a region located outside the closed region defined by the seal ring pattern 1241. Therefore, it is possible to avoid the issue that the alignment pattern on the scribe line is cut during the chip cutting process, causing the metal layer to be exposed and affecting the appearance of the chip. Moreover, since there is no need to worry about cutting the alignment pattern during the chip cutting process, the width of the scribe line may be further reduced, so that the chip units on the wafer are arranged more densely, thereby increasing the number of dies per wafer and increasing the chip throughput of each wafer. In an embodiment, the scribe line 130 may be reduced to between 60 microns and 80 microns, but the disclosure is not limited thereto.

In an embodiment, the alignment pattern 1242 and the seal ring pattern 1241 are electrically insulated and spaced apart from each other by a first distance d1. For example, the first distance d1 is approximately greater than 1 micron. In an embodiment, the outer edge of the alignment pattern 1242 is spaced apart from the inner edge of the scribe line 130 by a second distance d2 to further prevent the alignment pattern 1242 from being cut during the chip cutting process. In the present embodiment, the second distance d2 is approximately greater than 1 micron. In the present embodiment, the seal ring pattern 1241 includes an inner seal ring pattern 1241b surrounding the central region C1 and an outer seal ring pattern 1241a surrounding the inner seal ring pattern 1241b, and the outer seal ring pattern 1241a and the inner seal ring pattern 1241b are electrically insulated from each other. In the present embodiment, the alignment pattern 1242 is disposed between the scribe line 130 and the outer seal ring pattern 1241a.

In some embodiments, the peripheral metal pattern 124 may further include a plurality of dummy metal pads 1243 evenly distributed between the seal ring pattern 1241 and the alignment pattern 1242. The dummy metal pads 1243 may be electrically insulated from all of the seal ring pattern 1241, the alignment pattern 1242, and the chip circuit pattern 122. That is, the dummy metal pads 1243 may be electrically floating. The dummy metal pads 1243 may be evenly distributed in the wiring blanks in the chip units 120 to provide a more uniform pattern density, so that the chip units 120 may obtain a flatter surface after undergoing a planarization process (such as a CMP process).

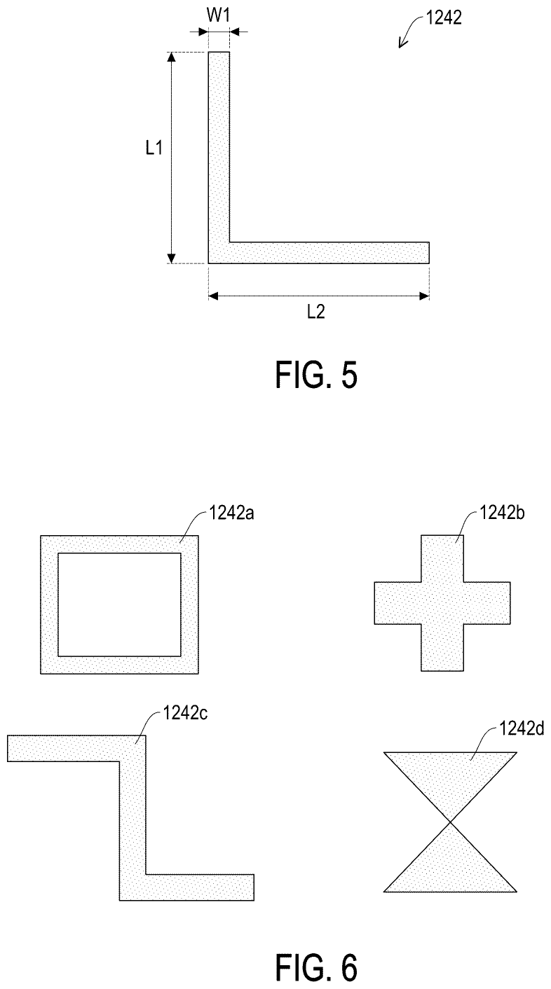

FIG. 5 is a schematic top view of an alignment pattern of a wafer structure according to an embodiment of the disclosure. Please refer to FIG. 4 and FIG. 5 simultaneously. In the present embodiment, the outer edge of the alignment pattern 1242 and the outer edge of the corresponding seal ring pattern 1241 are substantially collinear. Specifically, in the present embodiment, when viewed from the top view direction, the alignment pattern 1242 is L-shaped and has two substantially vertical outer edges (outside edges) that may be collinear with the outer edges of the corresponding seal ring pattern 1241 respectively, and may both be parallel to two sides of the corners of the chip units 120. The so-called “substantially vertical” here means that the included angle between the two substantially vertical outer edges of the L-shaped alignment pattern 1242 is approximately between 85 degrees and 95 degrees. In the present embodiment, lengths L1 and L2 of the two substantially vertical sides of the alignment pattern 1242 may be greater than or approximately equal to 10 microns, respectively, and the width of the two sides may be greater than or approximately equal to 2 microns. Of course, the present embodiment is only used for illustration, and the disclosure is not limited thereto.

FIG. 6 is a schematic top view of an alignment pattern of a wafer structure according to a different embodiment of the disclosure. Referring to FIG. 6, when viewed from the top view direction, the shape of the alignment pattern 1242 may also be other suitable shapes in addition to the L-shape as shown in FIG. 4. For example, an alignment pattern 1242a may be square-shaped, an alignment pattern 1242b may be cross-shaped, an alignment pattern 1242c may be Z-shaped, or an alignment pattern 1242d may be hourglass-shaped, etc. Each chip structure may have a plurality of alignment patterns, and the shape thereof may adopt one of the alignment patterns 1242, 1242a, 1242b, 1242c, 1242d, or may adopt a combination of the above shapes. Of course, the disclosure only lists several possible shapes of the alignment patterns, and the disclosure is not limited thereto. In an embodiment, the overall length and width dimensions of the alignment patterns may be greater than or approximately equal to 10 microns, and the width of the patterns may be greater than or approximately equal to 2 microns to facilitate identification by an image sensor.

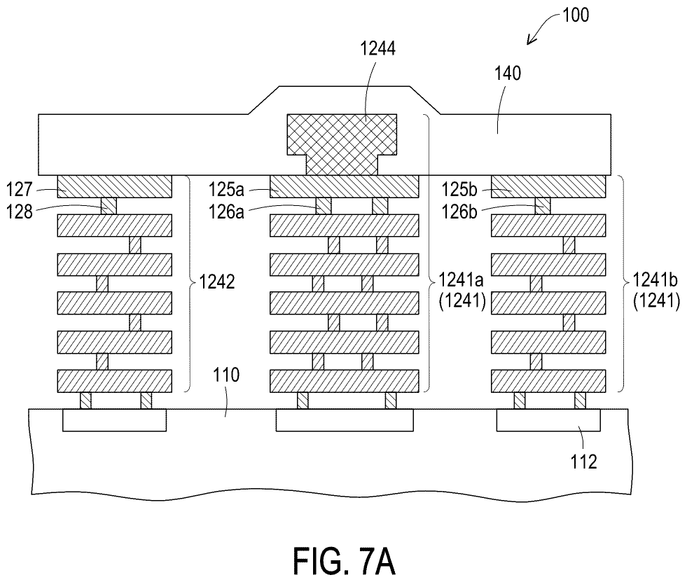

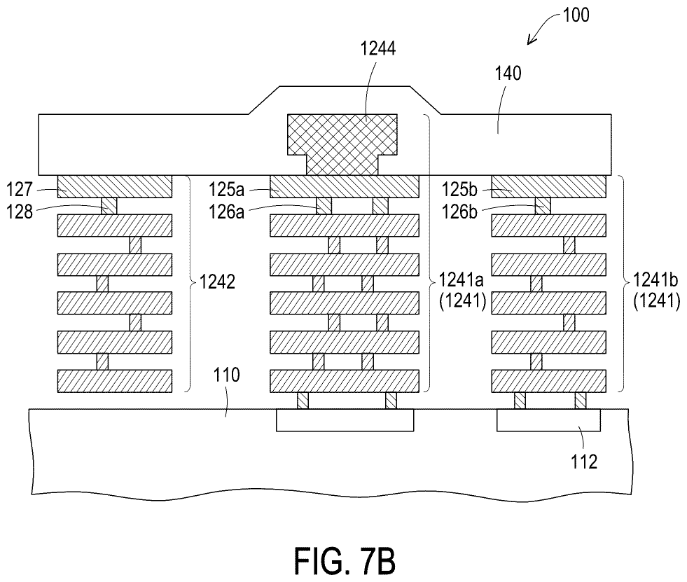

FIG. 7A is a partial cross-sectional view of a wafer structure according to an embodiment of the disclosure. Referring to FIG. 7A, in the present embodiment, the alignment pattern 1242 and the seal ring pattern 1241 are disposed on the same plane, and may be formed using the same photoresist pattern and by the same photolithography process. Specifically, the seal ring pattern 1241 includes a plurality of seal ring pattern layers disposed on the substrate 110 in an overlapping manner, the alignment pattern 1242 includes a plurality of alignment pattern layers disposed on the substrate 220 in an overlapping manner, each alignment pattern layer may be disposed on the same layer as the corresponding seal ring pattern layer, and each alignment pattern layer and seal ring pattern layer may all be formed using the same photoresist pattern and by the same photolithography process. In the present embodiment, the seal ring pattern 1241 may include the outer seal ring pattern 1241a and the inner seal ring pattern 1241b separated from each other by a dielectric material.

In an embodiment, the seal ring pattern 1241 may further include a pad layer 1244 that may be the uppermost layer in a plurality of seal ring pattern layers. In the present embodiment, the pad layer 1244 is disposed on the uppermost layer of the outer seal ring pattern 1241a, but the disclosure is not limited thereto. In an embodiment, a passivation layer 140 conformally covers the seal ring pattern 1241, the pad layer 1244, and the alignment pattern 1242 as shown in FIG. 7A to provide protection for electrical elements such as the underlying pad layer 1244 to help prevent or reduce moisture damage, mechanical damage, and radiation damage, and to also absorb or release thermal and/or mechanical stress during wafer cutting and packaging processes.

In some embodiments, the outer seal ring pattern 1241a of the seal ring pattern 1241 is formed by stacking a plurality of wiring layers 125a and inter-conductive line vias 126a on each other. Similarly, the inner seal ring pattern 1241b of the seal ring pattern 1241 is formed by stacking a plurality of wiring layers 125b and inter-conductive line vias 126b on each other. In an embodiment, the seal ring pattern 1241 may be connected to an element 112 of the substrate 110. In other embodiments, the seal ring pattern 1241 may be electrically insulated from the elements of the substrate 110. The alignment pattern 1242 is disposed outside the outer seal ring pattern 1241a and formed by stacking a plurality of wiring layers 127 and inter-conductive line vias 128 accordingly. In the present embodiment, the wiring layer 127 of each layer of the alignment pattern 1242 and the wiring layers 125a and 125b of each layer of the seal ring patterns 1241a and 1241b are all disposed on the same plane and may be formed simultaneously using a photolithography process.

FIG. 7A is a partial cross-sectional view of a wafer structure according to an embodiment of the disclosure. It should be mentioned that, the wafer structure 100 of the present embodiment is similar to the wafer structure of the previous embodiments. Therefore, the present embodiment adopts the same reference numerals and portions of the content from previous embodiments. Specifically, the same reference numerals are used to represent the same or similar elements, and the descriptions for the same techniques are omitted. The omitted portions are as described in the embodiments above and are not repeated in the present embodiment. Referring to FIG. 7A, in some embodiments, the alignment pattern 1242 is formed by stacking the plurality of wiring layers 127 and the inter-conductive line vias 128 on each other. The wiring layers 127 of the multi-layer alignment pattern 1242 may be disposed on the same plane as the wiring layers 125a and 125b of the multi-layer seal ring patterns 1241a and 1241b, respectively, and may be formed simultaneously using a photolithography process. In the present embodiment, different from the seal ring patterns 1241a and 1241b, the alignment pattern 1242 may be not stacked upward starting from the substrate 110. That is, the alignment pattern 1242 may be not connected to the substrate 110, but may be formed on any dielectric layer above the substrate 110, and then is stacked layer by layer upward, and, in the present embodiment, the alignment pattern 1242 is not connected to the element 112 of the substrate 110 by a via. That is, the alignment pattern 1242 does not include a via connected to the element 112 of the substrate 110. Of course, the present embodiment is only for illustration, and the disclosure does not limit the stacking method of the alignment pattern 1242.

Based on the above, in the wafer structure of the disclosure, the alignment pattern is disposed within the range defined by the scribe line and located at the region located outside the closed region defined by the seal ring pattern. Therefore, it is possible to avoid the issue that the alignment pattern on the scribe line is cut during the chip cutting process, causing the metal layer to be exposed and affecting the appearance of the chip. Moreover, since there is no need to worry about cutting the alignment pattern during the chip cutting process, the width of the scribe line may be further reduced, so that the chip units on the wafer are arranged more densely, thereby increasing the number of dies per wafer and increasing the chip throughput of each wafer.

What is claimed is:

1. A wafer structure, comprising:
a substrate;
a scribe line defining a chip unit on the substrate;
a chip circuit pattern disposed in a central region of the chip unit; and
a peripheral metal pattern disposed at a peripheral region of the chip unit and surrounding the central region, wherein the peripheral metal pattern comprises a seal ring pattern surrounding the central region and an alignment pattern disposed between the scribe line and the seal ring pattern.

2. The wafer structure of claim 1, wherein the seal ring pattern comprises a chamfer to vacate a corner region in the chip unit, and the alignment pattern is disposed in a corner region vacated by the chamfer.

3. The wafer structure of claim 1, wherein the peripheral metal pattern further comprises a plurality of dummy metal pads evenly distributed between the seal ring pattern and the alignment pattern.

4. The wafer structure of claim 1, wherein an outer edge of the alignment pattern is substantially collinear with an outer edge of the corresponding seal ring pattern.

5. The wafer structure of claim 1, wherein the alignment pattern is not overlapped with the scribe line when viewed from a top view direction.

6. The wafer structure of claim 1, wherein the chip circuit pattern is electrically insulated from the peripheral metal pattern.

7. The wafer structure of claim 1, wherein the alignment pattern is L-shaped, square-shaped, cross-shaped, Z-shaped, or hourglass-shaped.

8. The wafer structure of claim 1, wherein the seal ring pattern comprises a plurality of seal ring pattern layers disposed on the substrate in an overlapping manner.

9. The wafer structure of claim 1, wherein the alignment pattern comprises a plurality of alignment pattern layers disposed on the substrate in an overlapping manner and respectively disposed on a same layer as the corresponding plurality of seal ring pattern layers.

10. The wafer structure of claim 1, wherein the seal ring pattern comprises an inner seal ring pattern surrounding the central region and an outer seal ring pattern surrounding the inner seal ring pattern.

11. The wafer structure of claim 10, wherein the alignment pattern is disposed between the scribe line and the outer seal ring pattern.

12. A chip structure, comprising:
a substrate comprising a central region and a peripheral region surrounding the central region;
a chip circuit pattern disposed at the central region; and
a peripheral metal pattern disposed at the peripheral region and comprising a seal ring pattern surrounding the chip circuit pattern and an alignment pattern disposed outside a closed region defined by the seal ring pattern.

13. The chip structure of claim 12, wherein the alignment pattern is disposed between an outer edge of the chip structure and the seal ring pattern.

14. The chip structure of claim 12, wherein the seal ring pattern has a chamfer corresponding to a corner of the substrate, and the alignment pattern is disposed at the corner vacated by the chamfer.

15. A wafer structure, comprising:
a substrate;
a scribe line defining a chip unit on the substrate;
a chip disposed in the chip unit; and
a seal ring surrounding the chip and located between the scribe line and the chip; and
an alignment mark disposed between the scribe line and the seal ring.
